(19) United States
(12) Patent Application Publication
(10) Pub. No.: US 2021/0173363 A1
(43) Pub. Date: Jun. 10, 2021

(54) DEVICE FOR AUTOMATING THE INFRASTRUCTURE OF BUILDINGS BY MEANS OF THE IOT AND PROCESS FOR INSTALLING THE DEVICE WITH SIMPLIFIED METHODOLOGY IN ANY ENVIRONMENT, CONVERTING SAID ENVIRONMENT FROM A CONVENTIONAL ENVIRONMENT TO A SMART ENVIRONMENT

(71) Applicant: IOT COMPANY SOLUÇÕES TECNOLÓGICAS LTDA, Hortolândia (BR)

(72) Inventor: Erick FILZEK, Hortolândia (BR)

(21) Appl. No.: 17/059,364

(22) PCT Filed: May 29, 2018
(86) PCT No.: PCT/BR2018/050177

§ 371 Date: Nov. 27, 2020

(51) Int. Cl. G05B 15/02; G08C 23/04; G16Y 40/20; G16Y 20/30; G16Y 10/35; G08C 17/02

(52) U.S. Cl. CPC G05B 15/02; G08C 23/04; G16Y 40/20; H02J 7/00; G16Y 10/35; G08C 17/02; G16Y 20/30

(57) ABSTRACT

A device has as purpose the automation of building infrastructure through IoT and the corresponding device installation process, which has specific application in the areas of civil engineering and electric engineering, making use of the Internet of Things and information technology. Essentially, the device can be an automation device installed inside a standard box, at least 4x2, which projects phase, such automation device as a printed circuit board, the device mentioned with return to lamp or other device to which it is coupled, which further receives the neutral/common wire. In case of application in outlets, the printed circuit board receives the direct connection of the neutral/phase and/or phase/phase.

### FIELD OF INVENTION

This Invention Patent application refers to a device that has as purpose the automation of building infrastructure through IoT and the corresponding device installation process, which has specific application in the areas of civil engineering and electric engineering, making use of the Internet of Things and information technology.

### BACKGROUND OF THE INVENTION

Technically, it was observed that the market needs a solution that turns the line of building products (power outlets, switches, lighting, air conditioning and scenarios comprised by sensors) into smart ones, without, for that purpose, having to change the infrastructure already existing in the houses, buildings or other constructions.

It is frequent that users may not be motivated to change the infrastructure, since it has not been built to have the benefits resulting from IoT automation.

Notwithstanding, the current solutions are expensive and need the full change of the equipment. Many times the additional devices needed to permit the automation are large and not proportional to the infrastructure.

Therefore, this market needs the development of small, cheap devices that do not demand the change of the already existing infrastructure and, further, that are adequate to the standards of any country.

### STATE OF THE ART

In the state of the art, known document US2003/0050737, published on Mar. 12, 2003, describes an intelligent power system, where the multitude of electric junction boxes existing in a typical house or building is used for a unique combination of purposes, supporting several functionalities that have not yet been combined and permitting the facility of installation without new wiring. Normally, this system depends on the communication of the power line and uses electric wiring for distribution, monitoring and power control, as well as security, communications and audio/video entertainment and general network communication, such as file transfer and Internet connectivity. An underlying subject in this intelligent domestic power system permits that power-related information be collected through EMAC (energy monitoring and control) points normally installed at convenient places, such as electric joint boxes used for power outlets and wall switches. Besides being visually shown in the use or power measurement point, the information related to electric and thermal power is usually communicated through a power line data link to a centrally-located smart device such as PC, Residential Gateway or Smart Thermo-switch, which may be monitored, analyzed, profiled, viewed and also used to activate power-related control functions. The power consumption may be shown alternately in terms of cost per time. The power monitoring is also added to the electric circuit-breaker panel, offering an easier way of complementing the EMAC distributed points. In general, this smart power system creates a kind of “Bio-Feedback for Domestic Energy” making the consumer much more aware, permitting a more effective and efficient power use while creating a infrastructure for distribution and communication of electric power that permits significant advances in security, communication and comfort, besides higher control and power conservation.

Further, within the line of proposition of use of smart devices in general buildings, document WO201720933 of Jul. 12, 2017 may be highlighted, which refers to a residential automation system and a control method and, more specifically, to a domestic automation system in which the Internet of Things (IoT) is established, the residential automation system comprising: a first idle device including a first wireless communication; and a second inactive device including a second wireless communication unit, wherein, when a control signal is detected by the first inactive device, the first inactive device executes the first function and transmits a signal to perform the control in such a way that the second idle device executes a second function, through the first wireless communication unit, and the second idle device executes a second function as a response to the signal received from the first idle device through the second wireless communication unit.

Document US2017311115, published on Oct. 26, 2017, describes a cellular IoT (CIoT) device that may comprise a restricted coverage and/or processing device, for instance, devices operating mainly as MTC or M2M (for instance, sensing devices, controlling devices, etc.). These devices may have a limited or non-existing user interface and may be used for machines or devices that have little mobility. The CIoT devices may be implanted in scenarios of use, such as residential automation (i.e., security, appliances, energy packs, etc.), industrial automation and smart cities such as low-power devices (i.e., devices lasting for many years) and may be easily installed and operated in challenging coverage conditions, such as lower levels or underground levels of buildings. The CIoT devices may be provisioned to be connected to a cellular carrier network and to an associated CSP. The CSP may execute solutions such as, service portal, service registration, while the cellular carrier may provide the mass data channel to the CSP.

Document KR20170053238, published on May 16, 2017, describes a residential/building automation system based on the Internet of Things (IoT) for power saving and power through a cloud service and a method for their control. The residential/building automation system includes an analysis platform responsible for data analysis, a service platform for service management, a panel configured to show the status of the system and a panel management model configured to manage the panel. This invention completely cuts the reserve power that is wasted when a device is turned off, thus reducing the wasted energy.

Document US2015262443, published on Sep. 17, 2015, describes a technology that refers to the transformation of a common remote control into an IoT device. The IoT offers an opportunity to activate and extend the traditional technology products in a transparent and economic manner. As an example, a remote control for a garage door openers is transformed, thus permitting that smartphone users remotely activate the garage door openers from anywhere in the world. The transformation virtually eliminates the installation and integration difficulties, without losing any functionality. The devices with IoT technology also open the opportunity for the entire automation world and M2M benefits, such as automatically closing all garage doors after 9pm or when the people are far from home. This technology further leverages the power of smartphones, connected watches, IoT and M2M devices in a disruptive manner, changing the way how we live and interact with machines.

What can be observed as a common practice to the state-of-the-art documents is that they usually need the installation of their centrals in places with large accommodation areas, and further end up by having a high cost due to the large number of components, as a hardware.

As a general rule, although the devices are miniaturized, which may occur in some cases, they demand the installation of many transistors inserted in a same physical space, which theoretically reduces the cost, however, one must consider that a small plate also brings drawbacks, as it may generate an increase in temperature, due to lack of heat exchange, which demands cooling through the use of coolers or the like.

In other words, the obvious choice, as a general rule, consists of building a new product, that is, placing the devices for automation through IoT in another piece of hardware, which is the usual view of the manufacturer.

In the other hand, from the consumer point of view, it is obvious that electricians and installers present the prerogative that the wall junction boxes for switches and power outlets are themselves the end and the internal spaces remaining are not enough for any other use; if they find it difficult to install their own switches and power outlets, let alone the inclusion of an additional device in its interior.

### About the Invention

This Invention Patent application has the characteristic of providing for a device to automate the infrastructure of buildings through IoT, according to which there is the condensation of all electronic components into an arrangement that permits the non-generation of heat while being miniaturized as a printed circuit board, in a proper size to mandatorily fit inside standard in-wall switch boxes and power outlet boxes. According to the invention, its size would be enough to fit the interior of 4×2″ standard boxes, which today represent the smallest possible size in already existing infrastructures.

As regards the installation of the device, it requires only the removal of the switch or power outlet and the insertion of the printed circuit board that integrates the device, carrying out the corresponding electrical connection and replacing the switch or power outlet with the corresponding panel.

Once this is done, one must carry out the installation of the control software through any consumer interface media, such as: screens, PCs, Notebooks, Laptops, Smartphones and the like.

### General Description of the Invention

Based on studies and development focused on the mentioned problems, the inventor found, in a surprising manner, the possibility of inserting one to thirty simultaneous components inside, at least, one 4×2 standard box, occupying its internal space without prejudice to the operation of any of the internal components.

According to the invention, it is not necessary to create any new standard of outlets or switch boxes belonging to the state of the art, but using the already existing spaces in an arrangement intended for in-wall installation.

For the proper operation of the arrangement, a piece of software is required with capacity of actuation and direct control, without forgetting the maximum priority which is security. Optionally, the software may contain security systems existing in the state of the art, however preferably containing a solution of the inventor of this patent application, which is the installation of the blockchain as a form of security against external attacks, which may run in every points (switches, outlets, RF, etc.).

In other words, the operation of the device of the invention in symbiosis with the existing infrastructure permits the full accommodation of the finished product inside the confined space without requiring any electrical or structural change for the operation of the device.

The connection in circuits without neutral/common pin is a need in places where it is not present, or if there is any difficulty to pass an additional wire for the neutral/common circuit.

This integration with the infrastructure needs an electrical capture technology in series with the existing electronic circuit.

### DESCRIPTION OF THE DRAWINGS

The invention will be described below in a preferred embodiment and, for better understanding, references will be made to the attached drawings, in which the following is represented:

FIG. 1: Drawing of an outlet or switch (T) coupled to a lamp (4) according to the conventional technique;

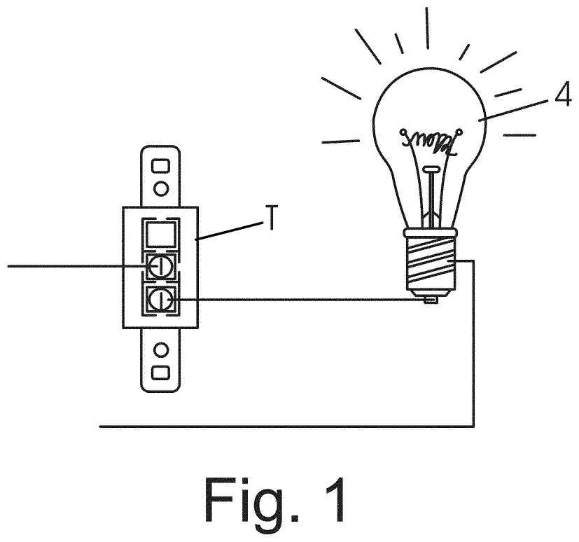

FIG. 2: General drawing of the invention showing, as an example, the device of the invention in a conventional outlet, connected to an electric lamp, so that the device be driven regardless of the lamp being on or off;

FIG. 3: Shows the automation device of the invention in one embodiment.

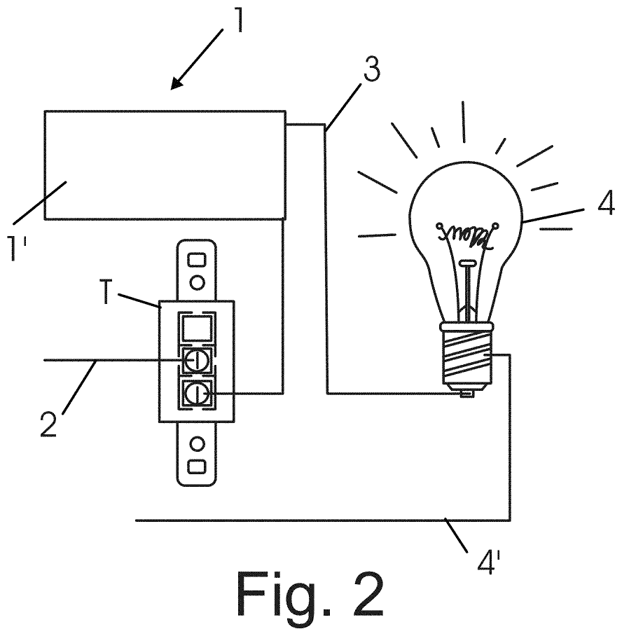

THE DEVICE FOR AUTOMATION OF THE INFRASTRUCTURE OF BUILDINGS THROUGH IoT AND A PROCESS FOR INSTALLATION OF THE DEVICE WITH A SIMPLIFIED METHODOLOGY IN ANY ENVIRONMENT, TURNING IT FROM A CONVENTIONAL DEVICE INTO A SMART DEVICE, under this invention patent application, comprises an automation device (1) that, according to FIG. 2, is installed inside a standard box, at least 4×2, which projects phase (2), such automation device (1) as a printed circuit board (1′), mentioned device (1) with return (3) to lamp (4) or other device to which it is coupled, which further receives the neutral/common wire (4′).

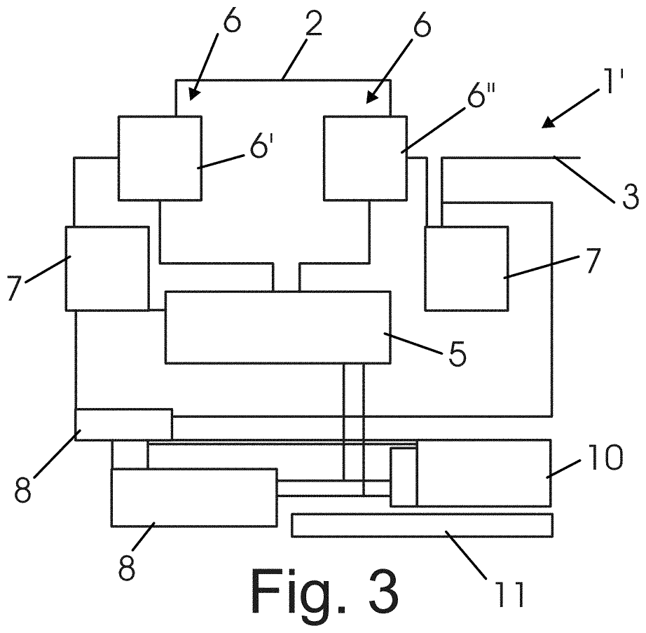

The automation device (1), under FIG. 3, configures a printed circuit board (1), inserted in the interior of the switch or outlet box, contemplating a Full CPU Block (5) connected to TRIACS (6), of which (6′) is a parasite load TRIACS and (6″) is an on-lamp (4) TRIAC, such Full CPU Block (5) connected to consumption current analysis components (7), with the provision of a diode bridge (8), and a consumption analysis source (9), while this set is coupled to a battery charger (10) and a rechargeable power cell (11); the TRIACS (6) are connected to phase (2), while the consumption current analysis (7) is connected to the return (3).

In the embodiment example shown in the invention, the source of consumption analysis is 5V 2A, while the battery charger (10) is a Lithium/LIPO battery, while the rechargeable power cell (11) is a 2S Lithium/LIPO >6V cell.

The automation device (1) configures, therefore, a printed circuit board (1′) through which many arrangements of devices can take place, and in one single plate one may have at least the arrangement of 6 devices that meet the need of plates for switches and outlets, namely:

### Devices:

Direct actuators for driving electric continuity—Relay;
Electronic actuators for dimmering of electric continuity—TRIAC (optional);
Consumption meter in electric continuity—ACS (current controller and meter—EMAC);
Radio-frequency transceiver (ISM) in several ranges of technologies (for example: Wi-Fi—2.4 a 5 GHz; Bluetooth 2.4 GHz; Lora 2.4/5.8 GHz, 900 to 1000 MHz and 433 MHz; communication in 433 MHz and 900 MHz);
Infrared transceiver;
Optionally with an EPA radio transceiver or any other technology that may come to exist.

Thus, according to the invention, the automation device (1) counts on a smart circuit, where the Full CPU Block (5) can be highlighted, for control and distribution of power by modulated pulses through power by pulses modulated through TRIACS (6) in series and parallel, having their control fully made by software. In the software, parasite loads are determined as necessary to place the circuit in operation, with lamp (4) being on or off, which occurs with “stealing of power” in the circuit, following the “power stealing” concept, where only what is necessary is taken from the circuit without changing the operation of what is connected in series with the return circuit.

The control by software created permits the full control of the openings of the TRIACS (6), thus permitting to modulate the wave pulse and cuts to alternate between the closing of the circuit for its total opening or the supply of the source/load of the battery (10).

The software controls the exact time in which the triggering of the parasite load TRIAC (6) for supply of the automation circuit must occur. While its consumption analysis is recorded, the software manages to equalize the shots, thus creating a chain of occurrence, executing the openings and transitions in such a way that the power circulating through the return does not permit the turning on or driving of a false on.

Thus, even though a lamp (4) is disconnected, the parasite load driving circuit must close the circuit of the lamp (4), however, it must not permit it to be turned on or to light, so that the TRIAC (6′) is driven for a time calculated according to the real consumption of the circuit, thus balancing the current and voltage required for its consumption and the load of the battery.

Therefore, according to the invention, it is necessary to have a rechargeable power cell (11) to keep the circuit operating due to the Full Block CPU (5), as it demands a higher load than the modulated instantaneous pulse, so that the demand for high storage of power motivated the inventor to include such rechargeable power cell (11) to work simultaneously with the CPU power supply circuit (5).

The printed circuit board (1′) may be applied in outlet installations, in the situation there is no intermediate circuit, and a direct connection of the neutral/phase and/or phase/phase occurs in such printed circuit board (1′).

Therefore, this Invention has the characteristic of providing for a device to automate the infrastructure of buildings through IoT, according to which there is the condensation of all electronic components into an arrangement that permits the non-generation of heat while being miniaturized as a printed circuit board, in a proper size to mandatorily fit inside standard in-wall switch boxes and power outlet boxes. According to the invention, its size would be enough to fit the interior of 4×2″ standard boxes, which today represent the smallest possible size in already existing infrastructures.

The process of installation of the automation device (1) requires the removal of panel of the box (C1) with the set of outlet or switch, installing the corresponding device (1), as a printed circuit board (1′) inside this box (C1), without the other components being changed, so that the automation device (1) be coupled to box (C1) and receives phase (2), while the return (3) is connected to the lamp (4) or other component.

1. A device for automation of the infrastructure of buildings through IoT, wherein an automation device is installed inside a standard box, at least 4×2, which projects phase, such automation device as a printed circuit board, with return to lamp or other device to which it is coupled, which further receives the neutral/common wire.

2. The device for automation of the infrastructure of buildings through IoT, according to claim 1, wherein the automation device counts on a smart circuit, where the Full CPU Block can be highlighted, for control and distribution of power by modulated pulses through TRIACS in series and parallel, having their control fully made by software.

3. The device for automation of the infrastructure of buildings through IoT, according to claim 1, wherein the automation device configures a printed circuit board, inserted in the interior of the switch or outlet box, contemplating a Full CPU Block connected to TRIACS, of which is a parasite load TRIAC and is an on-lamp TRIAC, such Full CPU Block connected to consumption current analysis components, with the provision of a diode bridge, and a consumption analysis source, while this set is coupled to a battery charger and a rechargeable power cell; the TRIACS are connected to phase, while the consumption current analysis is connected to the return.

4. The device for automation of the infrastructure of buildings through IoT, according to claim 1, wherein the printed circuit contemplates arrangements of devices, and in one single plate one may have at least the arrangement of 6 devices that meet the need of plates for switches and outlets, namely:
devices:
direct actuators for driving electric continuity—Relay;
electronic actuators for dimmering of electric continuity—TRIAC (optional);
consumption meter in electric continuity—ACS (current controller and meter—EMAC);
radio-frequency transceiver (ISM) in several ranges of technologies (for example: Wi-Fi—2.4 a 5 GHz; Bluetooth 2.4 GHz; Lora 2.4/5.8 GHz, 900 to 1000 MHz and 433 MHz; communication in 433 MHz and 900 MHz;
infrared transceiver;
optionally with an EPA radio transceiver or any other compatible technology.

5. The device for automation of the infrastructure of buildings through IoT, according to claim 3, wherein, the battery charger is a Lithium/LIPO battery, while the rechargeable power cell is a 2S Lithium/LIPO >6V cell.

6. A process of installation of device with simplified methodology in any environment, turning it from a conventional device to a smart device for the installation of the device under claim 1, wherein the process of installation of the automation device requires the removal of panel of the box with the set of outlet or switch, installing the corresponding device, as a printed circuit board inside this box, without the other components being changed, so that the automation device be coupled to box and receives phase, while the return is connected to the lamp or other component.

7. The process of installation of the device with simplified methodology in any environment, turning it from a conventional device to a smart device, according to claim 6, wherein, in case of being applied in outlets, the printed circuit board receives the direct connection of the neutral/phase and/or phase/phase.
